(19) United States
(12) Patent Application Publication
(10) Pub. No.: US 2025/0208208 A1
(43) Pub. Date: Jun. 26, 2025

(54) METHODS AND APPARATUS FOR FAULT ISOLATION WITH SCANNING ELECTRON MICROCROSCOPE PROBING

(71) Applicant: Intel Corporation, Santa Clara, CA (US)

(72) Inventors: Joshua Kevek, Portland, OR (US); Thaddeus John Cox, Lake Oswego, OR (US); Mitchell John Senger, Portland, OR (US); Christopher Michael Morgan, Portland, OR (US); Prasoon Joshi, Hillsboro, OR (US); Branden Long, Hillsboro, OR (US); Yang Su, Hillsboro, OR (US); Baohua Niu, Vancouver, WA (US); Charles Peterson, Hillsboro, OR (US); Martin Eric Gostasson von Haartman, Portland, OR (US)

(21) Appl. No.: 18/395,367

(22) Filed: Dec. 22, 2023

(51) Int. Cl. G01R 31/3177

(52) U.S. Cl. CPC G01R 31/3177

(57) ABSTRACT

Methods and apparatus for fault isolation with scanning electron microscope probing are disclosed. An example apparatus to test a circuit includes interface circuitry operatively coupled to an electron detector, the electron detector to output a signal corresponding to electron emissions from the circuit as the circuit is driven with a signal source and the circuit is rastered with an electron beam, machine readable instructions, and programmable circuitry to at least one of instantiate or execute the machine readable instructions to demodulate the signal, and generate an image based on the demodulated signal for determination of a condition of the circuit.

### FIELD OF THE DISCLOSURE

This disclosure relates generally to probing tools and, more particularly, to methods and apparatus for fault isolation with scanning electron microscope probing.

### BACKGROUND

Nano-probing tools have been utilized for their precision in fault isolation (FI) signal collection associated with semiconductor device fabrication processes. However, for nano-probing tools, throughput time for FI jobs typically scales in relation to a number of nodes that require probe contact, as well as a number of inputs and outputs (IOs) necessitated to drive a circuit of interest.

### BRIEF DESCRIPTION OF THE DRAWINGS

FIG. 1 is a block diagram of an example circuit condition analysis system constructed in accordance with teachings of this disclosure.

FIGS. 2A-2C depict aspects of examples disclosed herein.

FIG. 3 depicts an example image that can be produced by examples disclosed herein.

FIGS. 4A and 4B depict example waveforms that can be measured in examples disclosed herein.

FIG. 5 is a block diagram of an example circuit condition analyzer in accordance with teachings of this disclosure.

FIG. 6 is a flowchart representative of example machine readable instructions and/or example operations that may be executed, instantiated, and/or performed by example programmable circuitry to implement the circuit condition analyzer of FIG. 5.

FIG. 7 is a block diagram of an example processing platform including programmable circuitry structured to execute, instantiate, and/or perform the example machine readable instructions and/or perform the example operations of FIG. 6 to implement the circuit condition analyzer of FIG. 5.

FIG. 8 is a block diagram of an example implementation of the programmable circuitry of FIG. 7.

FIG. 9 is a block diagram of another example implementation of the programmable circuitry of FIG. 7.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Methods and apparatus for fault isolation with scanning electron microscope probing are disclosed. In known implementations, fault isolation (FI) probe flows leverage as few probe lands as possible to diagnose a circuit failure (e.g., in an integrated circuit) by leveraging an active stage of a scanning electron microscope (SEM) for single probe active voltage contrast or an additional probe for two-point open/short detection. However, with newer processes/implementations, circuit design has increased in complexity, and nodes have become increasingly difficult to access, thereby necessitating FI jobs that utilize cell-level and multi-cell probing.

Nano-probers typically include eight nano-probes in a chamber, and typical circuit cells have eight or more input and output pins. Therefore, probing an entire cell can necessitate use of all nano-probes available to the tool, and probing many cells requires lifting all probes and landing on each cell of interest. Accordingly, the throughput time for probing FI jobs will continue to increase for known methodologies that utilize direct probing.

In known implementations, probing a circuit with a relatively large amount of cells can necessitate a piecemeal approach. In particular, an operator lands probes on all inputs and output (IO) pins of a first cell in a circuit, and subsequently configures probes to drive the circuit. For example, when probing a single cell with eight IO pins, the operator can be necessitated to land three or more probes biased to ˜1 volt (V) to supply necessary power (Vcc) and logical highs, two probes to supply ground and logical lows, and three probes for voltage sensing. Other circuit configurations with additional inputs that exceed a number of possible probe lands for a system are also possible. For direct current (DC) probing, the operator can change input probe voltages and read a response on output probes to build out a truth table for a cell. If alternating current (AC) probing is necessitated, signal input probes are coupled to an arbitrary waveform generator to drive circuit inputs with square wave signals with different frequencies and phase offsets. Once all data from a first cell is captured, the operator then repeats the process for the next cell in a region of interest (ROI). If a pin arrangement of the next cell is not matched to a geometry of the first cell, then probes must be reconfigured to correctly arrange inputs and outputs to the next cell.

Some previous nano-probing FI techniques utilize a SEM image to characterize a behavior of a circuit driven by a nano-prober tool. In such known implementations, logic state imaging (LSI), which utilizes voltage contrast inherent in secondary electron images to determine if a circuit element is in a logical high or low in response to input, is utilized in nano-prober FI flows. In known LSI implementations, in an analogous manner to direct output probing, probes are landed on all inputs and set to high or low, as required by a circuit of interest and circuit elements are imaged with an SEM. Some disadvantages of this known technique are: i) the signal to noise ratio (SNR) of an LSI measurement is generally lower than direct probing (a signal-to-noise ratio (SNR) of approximately 5-10 compared to a range of 10-100), and ii) incompatibility with AC signal detection.

Another known technique is state modulated potential sensing (STAMPS). STAMPS has been utilized to determine a response of a circuit while the circuit is driven with AC signals. Two or more probes are landed on a sample to power the circuit, and another probe is landed to drive an input, such as a clock, with an AC signal to enable data inputs to the circuit. An additional probe is landed on a data-in input of the circuit, and LSI images are taken with a data high, then with a data low. In turn, the two images are subtracted to identify elements that respond to the data-in, and elements that do not respond. This known technique can be used to identify locations of defects in design-for-test (DFT) structures, such as breaks in a scan chain, for example. However, information about a dynamic response of the circuit to data-in running at speed is omitted.

Yet another known technique is called frequency-enhanced electric force microscopy (FE-EFM). FE-EFM has been utilized to read signals from metal interconnects of integrated circuits, which can include short loop test structures and full die structures. Reading the signals is performed by toggling an input of the circuit with an AC waveform running on a micro-probe, rastering an EFM tip across the circuit, and demodulating the electric force signal captured by the EFM detector at a frequency of an input signal. When the circuit is driven at a resonance frequency of the EFM tip, the EFM signal is amplified. This known technique can yield a high-resolution image (e.g., an image on the order of several nanometers (nm)) of the active circuitry running the AC signal within a field of view and provide FI related information in an analogous manner to the aforementioned STAMPS technique. This known technique can result in relatively long scan times (e.g., on the order of several minutes), and can also necessitate driving the circuit at or near tip resonance (e.g., 10 kilohertz (kHz)-1500 kHz), which can limit bandwidth of these tools.

In known AC probing implementations, an active circuit is driven with power and signal probes and a circuit response is measured with additional probes landed on the circuit outputs. Landing multiple probes on a sample can be tedious and difficult. In particular, landing a probe can push a sample to a new equilibrium position on a holder supporting the circuit being tested. However, even if a change in position is relatively small, the ROIs are on the order of 10 nanometers (nm) and, thus, can be sensitive to even slight movements. Further, each additional probe landed on the sample can move the sample to a new equilibrium position. In the process of adding sequential probes, it is typical for previously landed probes to shift laterally across the device, or to become unlanded.

Further, there can be additional difficulties in collecting the signals from the circuit. Particularly, AC signals collected can be relatively weak compared with their DC counterparts. For example, a signal input with a 1 V amplitude may yield a 1 millivolt (mV) output signal due to in-line resistance incurred at the probe contacts, and the circuits under test provide a current that is relatively weak against an input impedance of standard test equipment. Even further, signals running on outputs of cells with AC-modulated inputs can contain four or more convoluted levels (as opposed to just logical high and low), thereby yielding signals that can be difficult to interpret.

Examples disclosed herein can greatly reduce overhead and testing time by utilizing an electron beam of an SEM-based nano-prober as a scanning probe to measure circuit outputs over a relatively large area of a circuit, thereby removing a need to land tips on circuit output pins. As a result, examples disclosed herein can enable a reduction of a number of physical probes typically necessitated for multi-cell probing. Accordingly, examples disclosed herein can save time of output collections, thereby lowering throughput time for cell-level and multi-cell level probe jobs. Examples disclosed herein can also accurately determine a condition of a circuit. Examples disclosed herein can further detect and/or measure signals in a layer (e.g., buried signal layers).

Examples disclosed herein utilize an FI tool that incorporates a lock-in amplifier in conjunction with an imaging digitizer of an SEM-based nano-prober tool. According to examples disclosed herein, nano-probes are landed on inputs (e.g., all inputs) of a circuit of interest, and AC signals from a signal source (e.g., an arbitrary waveform generator, automated test equipment) can be used to drive the circuit. According to examples disclosed herein, the circuit is rastered with an electron beam from an emitter (e.g., an SEM emitter, an electron emitter, an electron beam emitter, etc.) and a secondary electron detector (SED) or other appropriate type of detector measures/detects the corresponding electron emissions and provides a signal to an image digitizer to capture and/or generate an image. Further, a signal (or a separate signal) is provided to the aforementioned lock-in amplifier to demodulate the signal provided thereto (e.g., by demodulating an image with a lock-in amplifier at the frequency of the signal of interest). As a result, a response of the circuit based on the input is imaged (e.g., directly imaged, represented as an image, etc.) in contrast to directly measuring each output with additional nano-probes. According to some examples disclosed herein, an SEM image (e.g., a raw SEM image) and a frequency map (e.g., a phase-resolved frequency map, amplitude frequency map, or an in-phase/quadrature frequency map, etc.) are compared to determine the condition.

According to some examples disclosed herein, the signal source provides an AC signal to the circuit to drive the circuit. In some examples, an electron emission from the emitter is modulated at a frequency corresponding to a modulation of a signal provided to the circuit. In some such examples, the lock-in amplifier is locked at and/or synchronized to the frequency. In some examples, a raw image and/or data pertaining to the raw image is demodulated by the lock-in amplifier. According to some examples disclosed herein, the demodulated image of the circuit of interest is compared to a circuit layout, the raw image, and/or a reference circuit demodulated image to determine the condition of the circuit of interest. Additionally or alternatively, an output waveform or an amplitude-based image is utilized to determine the condition.

As used herein, the term “condition” refers to an operational state of a circuit/circuitry including, but not limited to, a fault, a break, a short circuit, an open circuit, etc.

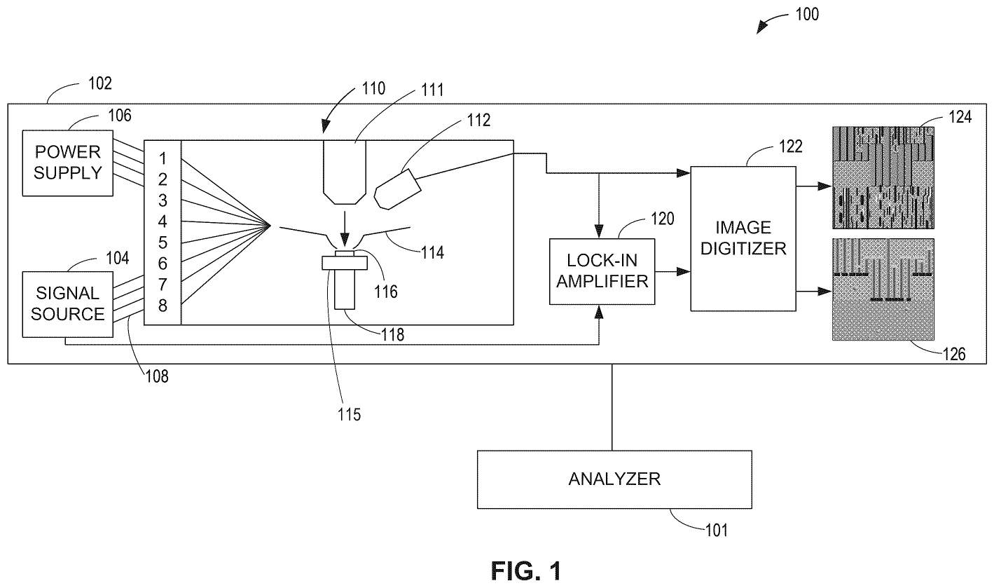

FIG. 1 is a block diagram of an example circuit condition analysis system 100 constructed in accordance with teachings of this disclosure. The circuit condition analysis system 100 of the illustrated example includes an analyzer (e.g., analyzer circuitry) 101 that includes and/or is communicatively coupled to an example test apparatus 102. In turn, the example test apparatus 102 includes a signal source (e.g., an arbitrary waveform generator (AWG), a function generator, automated test equipment, etc.) 104, a power supply 106, a probe IO lines/cables (e.g., probe interfaces, probe lines, etc.) 108, and an SEM 110. Accordingly, the example SEM 110 includes a beam emitter 111, an SED 112, probes 114 and a fixture 115 to hold a sample 116 that includes a circuit/circuitry to be tested, and a fixture (e.g., a support fixture) 118. According to the illustrated example of FIG. 1, the circuit condition analysis system 100 further includes an example lock-in amplifier 120 and an example image digitizer 122.

According to examples disclosed herein, to drive the circuit of the sample 116, the power supply 106 provides a voltage to the circuit of the probe IO lines/cables 108 and, in turn, the probes 114. In this example, the power supply 106 is implemented as a DC power supply and the signal source 104 provides clock and data signals to drive the circuit. In some examples, signals provided by the v104 run at one or multiple frequencies. In this example, the signal source 104 has a corresponding frequency referred to as a signal frequency (e.g., a synchronization frequency) herein referred to as f_{SYNC}.

To raster the circuit of the sample 116, the example beam emitter transmits and/or emits an electron beam toward the sample 116 while the circuit is driven with the signal source 104. While the electron beam is rastered over the sample, the electron beam is briefly dwelling on every pixel in the imaging window. Accordingly, when the electron beam lands on an object and/or feature of the circuit that has voltage toggling at the frequency, f_{SYNC}, the secondary electron emission from the object, which is sensitive to the voltage on the object, will also be modulated at the aforementioned frequency, f_{SYNC}.

To detect and/or measure emission (e.g., electron emissions) from the sample 116, the SED 112 can be mounted in an SEM column or a chamber. In this example, the SED 112 is implemented to collect, measure and/or detect secondary electrons emitted by the sample 116 and/or the circuit of the sample 116. In this example, the SED 112 provides an SED signal based on measured responses of the electron beam emitted/reflected from the sample 116. According to some examples disclosed herein, the SED signal from the SED 112 is divided and/or split with a first data stream going to (e.g., directly going to) the image digitizer 122 to capture and/or generate an SEM image, and a second data stream is routed to the lock-in amplifier 120 for demodulation.

To demodulate the SED signal provided from the SED 112, the example lock-in amplifier 120 is provided with the SED signal. In turn, the demodulated signal is provided to the example image digitizer 122. In other words, the example image digitizer 122 demodulates the SED signal and, in turn, provides the demodulated signal to the image digitizer 122. In this particular example, the SED signal is demodulated based on the frequency, f_{SYNC}, provided from the signal source 104.

The example lock-in amplifier 120, which demodulates the SED signal at a pixel level, may output a high signal if the modulation has a component at f_{SYNC}, and a low signal if the modulation does not have a component at f_{SYNC}. The demodulated SED signal can be routed to the image digitizer 122 to generate an image based on the high and low output of the lock-in amplifier 120. The demodulated SED signal may be scaled, manipulated and/or controlled to provide phase resolution in the resultant image, thereby enabling identifying of features that are toggling in or out of phase with respect to a reference signal. Additionally or alternatively, the demodulated SED signal is utilized to generate an output waveform, an in-phase/quadrature frequency map and/or an amplitude-based image.

To generate at least one image for determination of a condition of the circuit, the image digitizer 122 of the illustrated example utilizes the SED signal from the SED 112 (e.g., via the first data stream), as well as the demodulated SED signal from the lock-in amplifier 120. In this example, the image digitizer 122 generates an SEM image 124 (e.g., a raw SEM image), as well as a phased-resolved frequency map 126. However, any other type of waveform, amplitude-based image, etc. can be implemented instead. According to some examples disclosed herein, the SEM image 124 is compared to the phased-resolved frequency map 126 to determine a condition and/or status of the circuit of the sample 116. Additionally or alternatively, the phased-resolved frequency map 126 is compared to an expected or predetermined phased-resolved frequency map.

In some examples, the image digitizer 122 plots the raw SEM image 124 and the demodulated SEM/SED 126 image in a relatively simultaneous manner. According to some examples disclosed herein, the combination of images 124, 126 can provide information with respect to behavior of the circuit under test, including, but not limited to, locations of hard opens/shorts, locations of resistive shorts or soft opens, and feedback on subtle Vₘᵢₙ shifts or timing failures in the circuit. According to examples disclosed herein, probes, a significant number of IO connections, or additional test equipment are not necessitated to gather output signals from a sample for data acquisition, thereby easing the difficulties intrinsic to traditional AC direct nano-probing methodologies.

For lock-in based signal detection, according to examples disclosed herein, it can be advantageous to average the collected signal over many periods of the signal's oscillation, for example. In particular, an averaging time (T) can be significantly larger than a signal period (T≳100/f_{SYNC}) (e.g., for a 1 MHz signal, T≈100 μs). For a lock-in SEM-prober, an averaging time is determined by a pixel dwell time of an SEM. Accordingly, relatively longer scans can generate images with larger SNR. Known SEDs can detect DC (0 Hz) signals (e.g., LSI) but are bandwidth limited to 5-100 MHz. In contrast, examples disclosed herein can be advantageous for signal collections where the frequency of interest is below 100 MHz with continuous diminishment for signals above the SED bandwidth cutoff.

According to examples disclosed herein, applying an AC signal to a probe tip proximate the electron beam causes electromagnetic interference to the beam's propagation. Accordingly, the probe will charge and discharge at the frequency applied to the probe, thereby creating a fast-switching electric and magnetic field that causes the beam to jitter between two positions corresponding to the probe's high and low. Because the image is demodulated at the same frequency of the jitter, the lock-in signal corresponding to circuit activity may be mixed with artifactual “false” signals created by SEM beam jittering between light and dark objects.

The effects of the aforementioned jitter can be mitigated. The AC signal can be modulated to reduce the effect. For example, if the signal runs at 50% duty cycle, the beam will, as a result, spend half the time in one extreme of the jitter, and half in the other, which increases (e.g., maximizes) the artifactual signal strength. Alternatively, the AC signal duty cycle may be reduced to 20%, thereby biasing the jitter to one extreme over the other, for example. In such an example, the component of the signal created by the jitter will be reduced to 1:4 in comparison to a 50% duty cycle, and, thus, increase the SNR for the circuit activity. Further, to mitigate the jitter, an additional probe can be implemented to cancel the electromagnetic signal. According to examples disclosed herein, the AC signal input to the sample may be divided, split and/or forked and input to a second probe tip lifted above the sample. By moving the probe carrying the redundant AC signal to a precise location opposite the driver probe, the user may be able to produce a net zero added field at a position of the beam and diminish an overall amount of jitter.

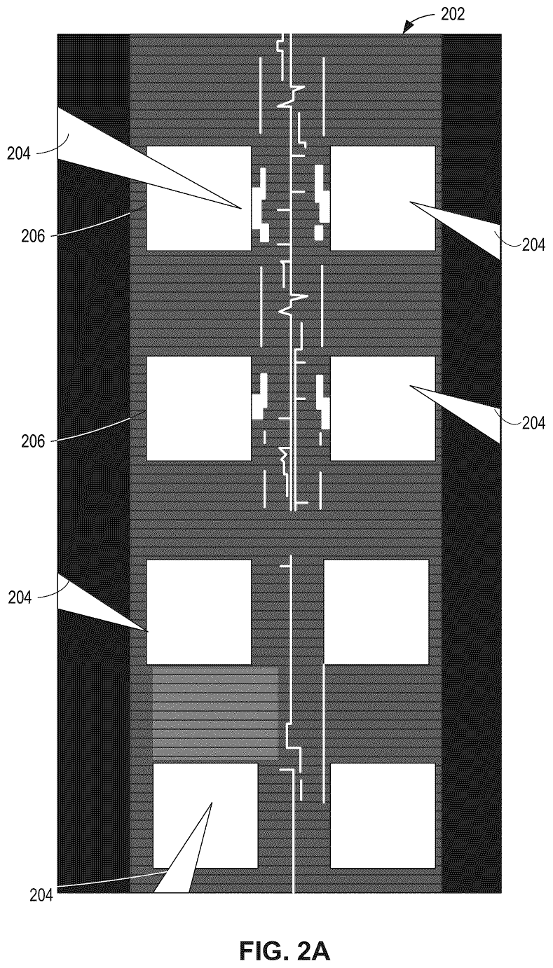

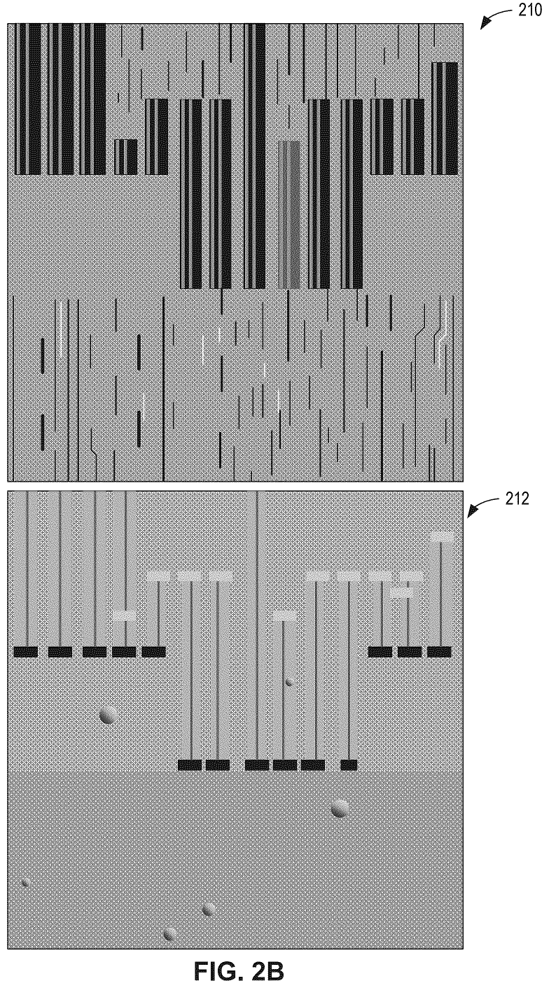

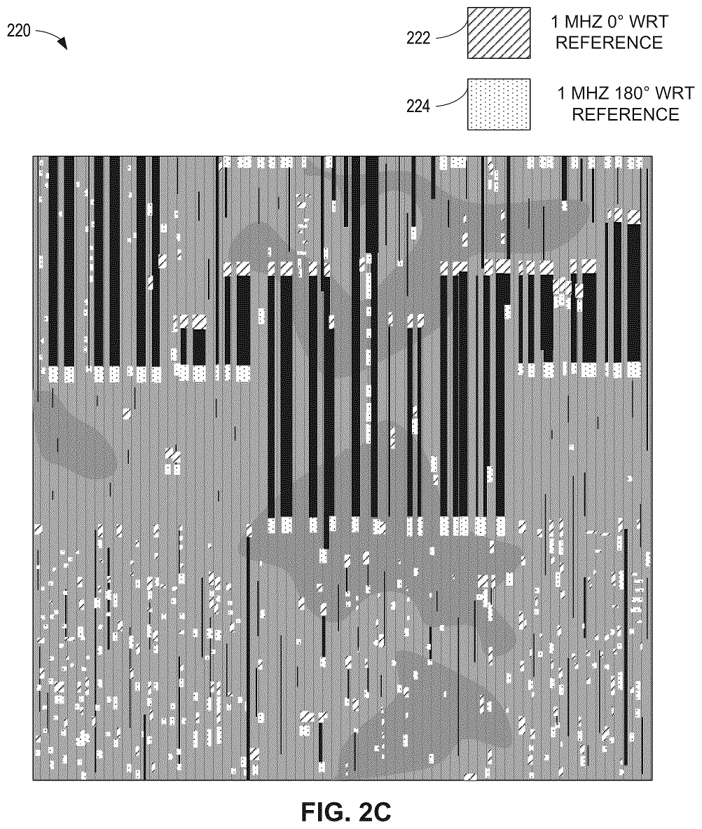

FIGS. 2A-2C depict aspects of examples disclosed herein. Turning to FIG. 2A, an example micro-probe configuration for driving a short-loop DFT structure is shown with respect to a top metal layer of a circuit. In this example, an area 202 corresponds to a region of interest. In this example, probes (e.g., coaxial probes) 204 are depicted coupled and/or mounted to inputs 206 (e.g., metal structures pads, test pads, etc.). In this example, the aforementioned short-loop DFT structure prepared on the top metal layer is imaged, a detector signal corresponding to the SEM-prober is routed to the input of an auxiliary lock-in amplifier, and the lock-in amplifier output is connected to an analog input of a digitizer module. Further, a single micro-probe (e.g., a micro-probe larger than its nano-probe counterparts) was connected to a signal source, such as an AWG, to provide a clock-in signal to a clock pad of the DFT structure. In this particular example, three other micro-probes were landed to provide the power (Vcc) and ground (Vss) to the circuit.

FIG. 2B depicts example images 210, 212. The example image 210 corresponds to an SEM image of a scan chain and/or a scan chain structure. In the illustrated view of FIG. 2B, an area of the image 210 corresponds to a zoomed-in view of the aforementioned area 202 shown in FIG. 2A. With respect to example image 212, an example electron signal imaging map (ESIM) of a circuit reveals features toggling at 1 megahertz (MHz) in-phase (lighter portions) and out-of-phase (black) with respect to a reference signal of a signal source, such as an AWG, for example, is depicted. In this example, a noise level is in a middle/intermediate region/portion of the white-black color scale with gray representing no signal or weak signal, for example.

FIG. 2C depicts an example overlay (e.g., an overlay image, on overlay map, etc.) 220 of the image 210 onto the image 212 of FIG. 2B. The example overlay 220 of the illustrated example of FIG. 2C is generated to localize the ESIM signals against physical features of the circuit. In this example, a region 222 corresponds to a 1 MHz signal that has a phase difference of approximately 0° with respect to a reference signal (e.g., a signal source reference signal, an AWG reference signal, etc.) while a region 224 corresponds to a 1 MHz signal that is out of phase with the reference signal by 180°. As can be seen in the example of FIG. 2C, different phase characteristics correspond to different regions of the image 210.

Examples disclosed herein enable capturing the image 210 in combination with lock-in outputs of image 212 (shown in FIG. 2B) in a relatively simultaneous manner. According to some examples disclosed herein, a 1 kV electron beam and 100 microsecond (μs) pixel dwell time can be utilized to capture and/or collect an image. According to some examples disclosed herein, a demodulated image from an active DFT structure is overlaid on an SEM image, such as the image 220 depicted in FIG. 2C. Accordingly, such an imaging technique in accordance with teachings of this disclosure can reveal AC activity and/or characteristics of numerous circuit features of an image and/or mapping without landing an output probe. According to examples disclosed herein, a demodulated signal can be indicated and/or reported with phase resolution to indicate whether a signal is in-phase or out-of-phase with respect to a reference signal, thereby revealing points in a scan chain where a clock signal is flipped after transmitting via a constituent inverter, for example.

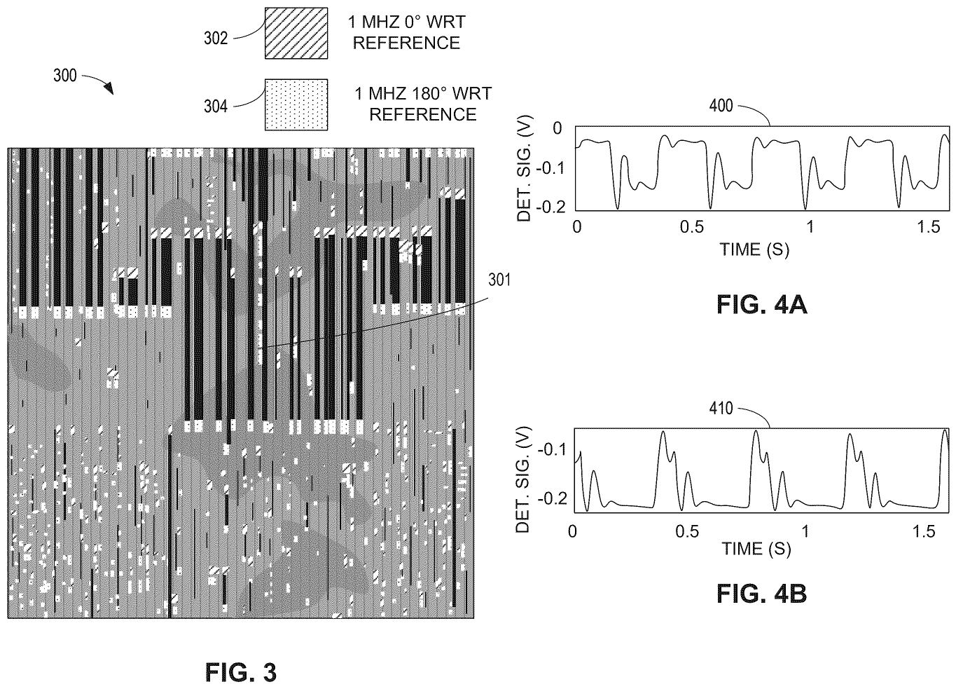

FIG. 3 depicts an example image 300 that can be produced by examples disclosed herein. The image 300 of the illustrated example corresponds to a zoomed-in view of the image 220 described above in connection with FIG. 2C. In the illustrated example of FIG. 3, a clock-in signal 301 is highlighted. In this example, regions 302 corresponds to a 1 MHz signal that has a phase difference of approximately 0° with respect to a reference signal (e.g., an AWG reference signal) while regions 304 correspond to a 1 MHz signal that is out of phase with the reference signal by 180°.

According to the examples of FIGS. 3-4B, an example lock-in amplifier includes a capability to average a collected signal over multiple periods. In particular, this capability can be utilized to capture a shape of a signal running at a particular point on a sample by directing a beam at a single pixel in contrast to rastering an entire field of view, for example. Captured waveforms based on a clock input of a circuit shown in FIG. 3 are depicted in FIGS. 4A and 4B. In this example, without landing an output probe, a 250 kHz clock-in signal is captured when the input signal has a 50% duty cycle depicted in FIG. 4A and a 20% duty cycle depicted in FIG. 4B.

FIGS. 4A and 4B depict example waveforms that can be measured in examples disclosed herein. Turning to FIG. 4A, an example waveform 400 corresponds to a collected waveform of a clock signal as measured with a lock-in amplifier. In this particular example, a clock is generated with the following parameters: 700 millivolt (mV) peak-to-peak, 250 kHz signal in combination with the 50% duty cycle mentioned above.

FIG. 4B depicts an example waveform 410 that corresponds to a collected waveform of the clock signal as measured with the lock-in amplifier. In this example, the waveform 410 is generated with a clock having the following parameters: 700 mV peak-to-peak, 250 kHz, signal with the aforementioned 20% duty cycle. However, in addition to the examples of FIGS. 4A and 4B, any other appropriate waveform parameters can be measured instead.

While example signals are collected from or at a surface metal in examples disclosed herein, alternatively, signals can be collected to isolate defects from beneath an outer surface and/or layer of a circuit (e.g., internal or within the circuit) while surface probes are landed. To that end, in terms of FI tools/labs, available preparation tools can precisely and/or accurately remove material from metal interconnects as well as a supporting dielectric (e.g., a supporting dielectric material/body, etc.) of an integrated circuit without creating shorts or damaging the circuit. These tools may be utilized in examples disclosed herein to prepare samples in which a targeted signal of interest is in a relatively close proximity of landed probe inputs, but not directly on (or above) a surface of a circuit. Accordingly, if the SEM beam can reach and resolve an excavated signal, example disclosed herein can collect an output therefrom. Additionally, it has also been demonstrated that increasing beam energy advantageously enables secondary electron generation to emanate from metal lines beneath or under the surface. Accordingly, because examples disclosed herein can probe outputs with an electron-beam in contrast to landed tips, increased beam energies may be implemented to probe for buried signals, as well as defects beneath the surface that are otherwise generally inaccessible to conventional direct probing.

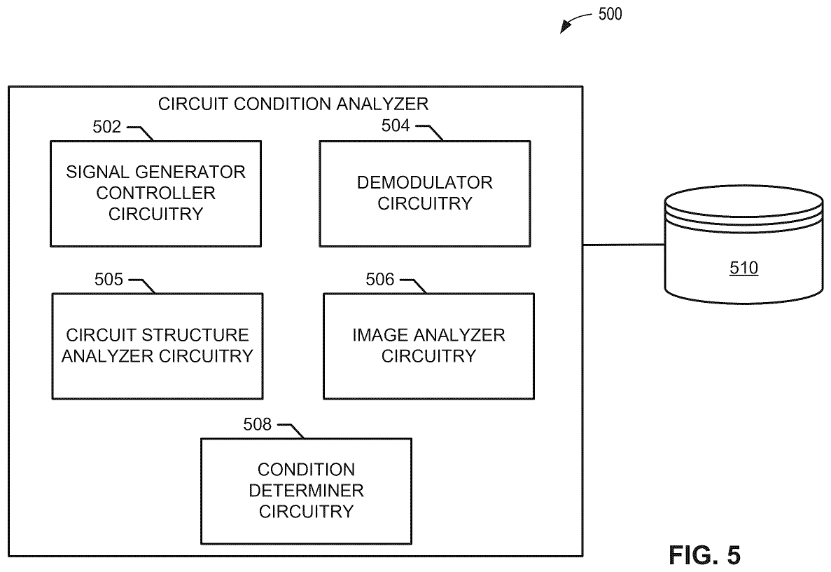

FIG. 5 is a block diagram of an example circuit condition analyzer 500 to generate at least one image for a determination of a condition and/or state of a circuit (e.g., a sample with a circuit, an integrated circuit, etc.). The example circuit condition analyzer 500 of FIG. 5 can be implemented in the example circuit condition analysis system 100 and/or the analyzer 101 shown in FIG. 1. The example circuit condition analyzer 500 may be instantiated (e.g., creating an instance of, bring into being for any length of time, materialize, implement, etc.) by programmable circuitry such as a Central Processor Unit (CPU) executing first instructions. Additionally or alternatively, the circuit condition analyzer 500 of FIG. 5 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 5 may, thus, be instantiated at the same or different times. Some or all of the circuitry of FIG. 5 may be instantiated, for example, in one or more threads executing concurrently on hardware and/or in series on hardware. Moreover, in some examples, some or all of the circuitry of FIG. 5 may be implemented by microprocessor circuitry executing instructions and/or FPGA circuitry performing operations to implement one or more virtual machines and/or containers.

The circuit condition analyzer 500 of the illustrated example includes example signal generator controller circuitry 502, example demodulator circuitry 504, example circuit structure analyzer circuitry 505, example image analyzer circuitry 506, and example condition determiner circuitry 508. According to some examples disclosed herein, the circuit condition analyzer 500 includes and/or is communicatively coupled to an example data storage 510.

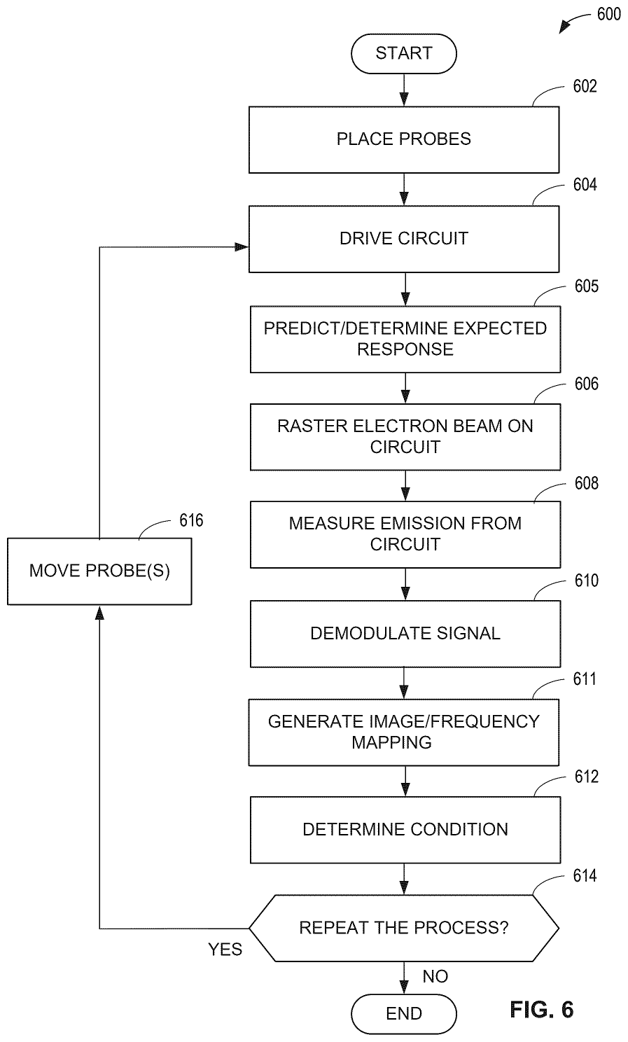

In the illustrated example of FIG. 5, the signal generator controller circuitry 502 controls/directs parameters and/or behavior of a signal generated by a signal source (e.g., the signal source 104, an AWG, automated test equipment, etc.). Additionally or alternatively, the signal generator controller circuitry 502 controls a synchronization frequency, f_{SYNC}, that is utilized to drive the circuit, as well as for demodulation of an SED signal and/or an SEM image (e.g., a raw SEM image) corresponding to a response of the circuit. In some examples, the signal generator controller circuitry 502 is instantiated by programmable circuitry executing signal generator controller instructions and/or configured to perform operations such as those represented by the flowchart of FIG. 6.

According to some examples disclosed herein, the demodulator circuitry 504 is implemented to control and/or direct a lock-in amplifier (e.g., the lock-in amplifier 120) or other demodulation device to demodulate an SED signal that is provided by an SEM and/or an SED. In some such examples, the lock-in amplifier utilizes the aforementioned frequency synchronization signal, f_{SYNC}, to demodulate the SED signal. In turn, the example demodulator circuitry 504 provides the demodulated SED signal to an image digitizer (e.g., the image digitizer 122). In some examples, the demodulator circuitry 504 is instantiated by programmable circuitry executing signal analyzer instructions and/or configured to perform operations such as those represented by the flowchart of FIG. 6.

In some examples, the structure analyzer circuitry 505 is implemented to characterize a structure of the circuit and/or an expected/predicted characteristic behavior or output of the circuit. In some examples, the circuit structure analyzer circuitry 505 can determine information corresponding to an expected frequency response of the circuit. For example, the circuit structure analyzer circuitry 505 can predict an area, portion and/or region of the circuit at which a frequency response is to be expected to be exhibited based on a given input (e.g., a known input, a predefined input, etc.) provided to the circuit. In some examples, the circuit structure analyzer circuitry 505 is instantiated by programmable circuitry executing structure analyzer instructions and/or configured to perform operations such as those represented by the flowchart of FIG. 6.

The example image analyzer circuitry 506 is implemented to generate at least one image, output waveform and/or mapping corresponding to a response of the circuit via the image digitizer. In this example, the image analyzer circuitry 506 utilizes the demodulated SED signal from the lock-in amplifier to generate the at least one image and/or mapping, which can include a two-dimensional (2D) and/or planar representation of the circuit. In other examples, a three-dimensional (3D) representation of the circuit is obtained. In some examples, the example image analyzer circuitry 506 generates an SEM image that is not demodulated (e.g., a raw SEM image). In particular, the SEM image may be generated by the SED signal such that the SED signal is provided to (e.g., forked to) both the image digitizer and the lock-in amplifier. In the illustrated example of FIG. 5, the image analyzer circuitry 506 maps and/or identifies pixels where the signal toggles at f_{SYNC} (e.g., onto an unprocessed or raw SEM image). Additionally or alternatively, the image analyzer circuitry 506 demodulates an image and/or image information corresponding to the circuit (e.g., based on the frequency synchronization signal, f_{SYNC}). In some examples, the image analyzer circuitry 506 is instantiated by programmable circuitry executing mage analyzer instructions and/or configured to perform operations such as those represented by the flowchart of FIG. 6.

In the illustrated example of FIG. 5, the condition determiner circuitry 508 is implemented to determine a condition of the circuitry. For example, the condition determiner circuitry 508 can compare the aforementioned image and/or mapping generated based on demodulated SED signals to another image (e.g., a raw SEM/SED image), which may be the aforementioned SEM image or an expected imaging/mapping. Additionally or alternatively, the image and/or mapping generated based on demodulated SED signals is compared to a predicted and/or expected frequency response of the circuit. In some examples, the condition determiner circuitry 508 is instantiated by programmable circuitry executing condition determiner instructions and/or configured to perform operations such as those represented by the flowchart of FIG. 6.

In some examples, the data storage 510 is implemented to store data corresponding to a sample (e.g., a circuit of a sample) being tested. In some such examples, the data storage 510 can store expected behavior (e.g., an expected frequency response, expected mapping, etc.) of the aforementioned sample. Additionally or alternatively, the data storage 510 stores demodulated SED signals and/or images corresponding to demodulated SED signals.

While an example manner of implementing the circuit condition analyzer 500 of FIG. 5 is illustrated in FIG. 5, one or more of the elements, processes, and/or devices illustrated in FIG. 5 may be combined, divided, re-arranged, omitted, eliminated, and/or implemented in any other way. Further, the example signal generator controller circuitry 502, the example demodulator circuitry 504, the example circuit structure analyzer circuitry 505, the example image analyzer circuitry 506, the example condition determiner circuitry 508, and/or, more generally, the example circuit condition analyzer 500 of FIG. 5, may be implemented by hardware alone or by hardware in combination with software and/or firmware. Thus, for example, any of the example signal generator controller circuitry 502, the example demodulator circuitry 504, the example circuit structure analyzer circuitry 505, the example image analyzer circuitry 506, the example condition determiner circuitry 508, and/or, more generally, the example circuit condition analyzer 500, could be implemented by programmable circuitry in combination with machine readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example circuit condition analyzer 500 of FIG. 5 may include one or more elements, processes, and/or devices in addition to, or instead of, those illustrated in FIG. 5, and/or may include more than one of any or all of the illustrated elements, processes and devices.

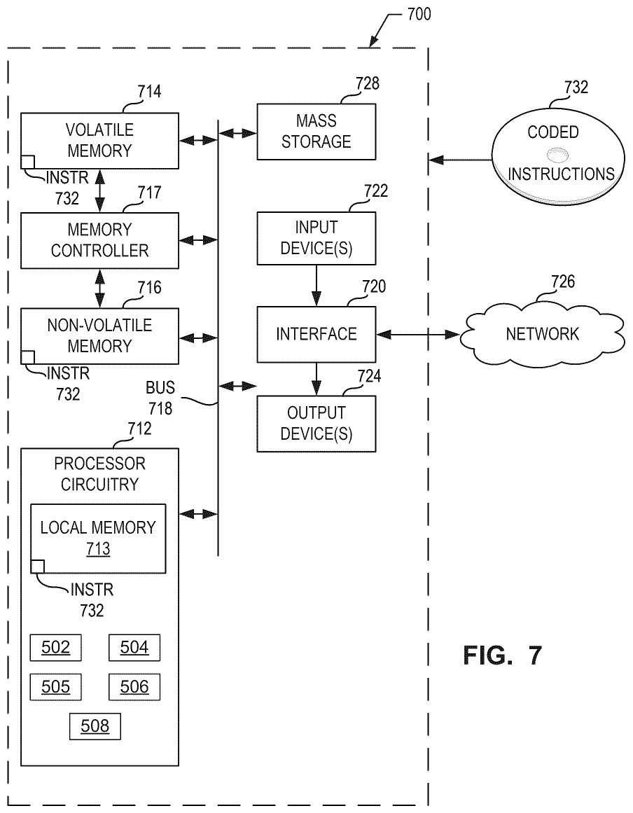

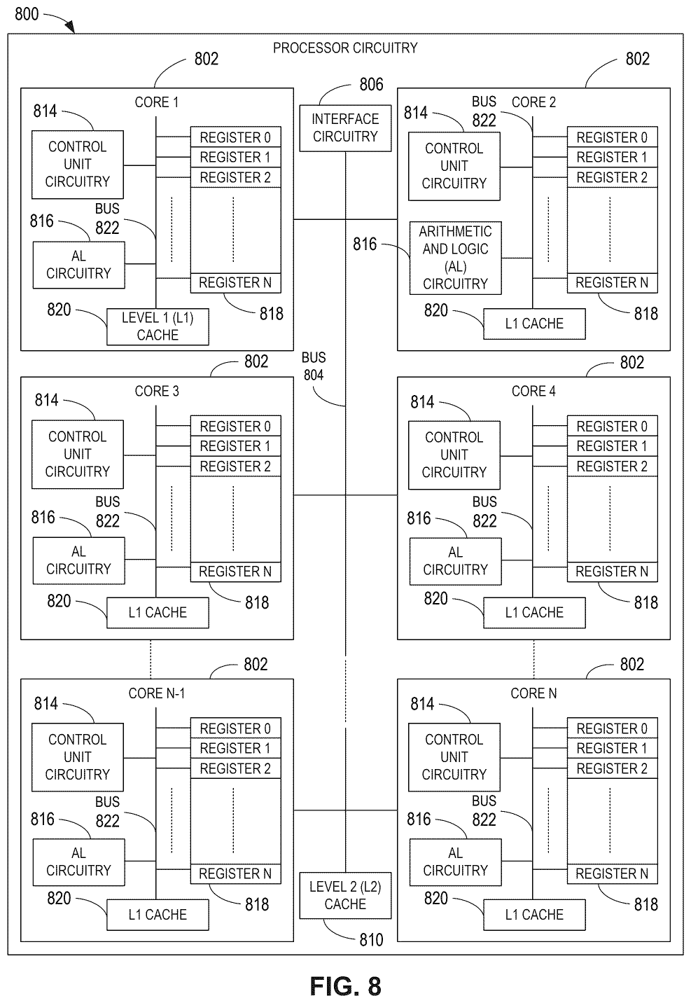

A flowchart representative of example machine readable instructions, which may be executed by programmable circuitry to implement and/or instantiate the circuit condition analyzer 500 of FIG. 5 and/or representative of example operations which may be performed by programmable circuitry to implement and/or instantiate the circuit condition analyzer 500 of FIG. 5, is shown in FIG. 6. The machine readable instructions may be one or more executable programs or portion(s) of one or more executable programs for execution by programmable circuitry such as the programmable circuitry 712 shown in the example processor platform 700 discussed below in connection with FIG. 7 and/or may be one or more function(s) or portion(s) of functions to be performed by the example programmable circuitry (e.g., an FPGA) discussed below in connection with FIGS. 8 and/or 9. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart illustrated in FIG. 6, many other methods of implementing the example circuit condition analyzer 500 may alternatively be used. For example, the order of execution of the blocks of the flowchart may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 6 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 6 is a flowchart representative of example machine readable instructions and/or example operations 600 that may be executed, instantiated, and/or performed by programmable circuitry to determine a condition (e.g., an operating condition) of a circuit (e.g., an integrated circuit, a circuit of a sample, etc.). The example machine-readable instructions and/or the example operations 600 of FIG. 6 begin at block 602, at which at least one probe is placed onto the circuit. In this example, two probes are placed onto metallized surfaces on an external surface of the circuit.

At block 604, the signal generator controller circuitry 502 causes the circuit to be driven with a signal source (e.g., the signal source 104) and a power supply (e.g., a DC power supply). In this example, the signal source provides and/or causes at least portion of the circuit to exhibit activity related to a frequency (e.g., a synchronization frequency) of the signal from the signal source that drives the circuit.

At block 605, in some examples, the circuit structure analyzer circuitry 505 determines and/or predicts an expected response (e.g., an expected frequency response) of the circuit. In some such examples, the expected response corresponds to an expected frequency response corresponding to an input signal from the aforementioned signal source.

At block 606, the circuit is rastered with an electron beam from an SEM (e.g., the SEM 110). In this example, an electron beam emitter is utilized to raster at least a portion of the circuit with the electron beam. In some examples, the electron beam is confined to a portion of the circuit. In other examples, the beam is emitted over an entirety of the circuit.

At block 608, an SED is to measure (e.g., the SED is caused to measure) emissions (e.g., reflective emissions) from the circuit. In this example, the SED provides and/or outputs an SED signal based on the aforementioned response from an outer surface (e.g., an emission from the outer surface) of the circuit as the circuit is driven.

At block 610, the example demodulator circuitry 504 causes the lock-in amplifier to demodulate the SED signal. In the illustrated example of FIG. 6, the lock-amplifier utilizes a frequency synchronization signal from the signal source to demodulate the SED signal.

At block 611, the example image analyzer circuitry 506 generates at least one image, waveform and/or frequency mapping corresponding to the demodulated SED signal. In this example, the at least one image and/or frequency mapping corresponds to a 2-D representation indicating portions thereof that exhibit behavior in response to the circuit being driven. In some examples, the portions are overlayed on an image of the circuit.

At block 612, the example condition determiner circuitry 508 determines the condition of the circuit. For example, the condition determiner circuitry 508 compares the generated image and/or mapping corresponding to the demodulated signal to a raw SEM image and/or a mapping corresponding to an expected response of the circuit. In some examples, the condition determiner circuitry 508 compares the image and/or frequency mapping corresponding to the demodulated signal at two different frequencies. In some examples, the image and/or frequency mapping corresponding to the demodulated signal is subtracted from the raw SEM image and/or frequency mapping.

At block 614, it is determined whether to repeat the process. If the process is to be repeated (block 614), control of the process proceeds to block 616. Otherwise, the process ends. The determination may be based on whether additional circuits and/or circuit portions are to be tested. Additionally or alternatively, the determination may be based on whether to test the circuit at a different frequency from the frequency previously used to drive the circuit.

At block 616, in some examples, at least one probe is moved (e.g., to another test location, to another circuit, etc.). For example, the at least one probe is moved from one test location to another test location.

FIG. 7 is a block diagram of an example programmable circuitry platform 700 structured to execute and/or instantiate the example machine-readable instructions and/or the example operations of FIG. 6 to implement the circuit condition analyzer 500 of FIG. 5. The programmable circuitry platform 700 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 700 of the illustrated example includes programmable circuitry 712. The programmable circuitry 712 of the illustrated example is hardware. For example, the programmable circuitry 712 can be implemented by one or more integrated circuits, logic circuits, FPGAs, microprocessors, CPUs, GPUs, DSPs, and/or microcontrollers from any desired family or manufacturer. The programmable circuitry 712 may be implemented by one or more semiconductor based (e.g., silicon based) devices. In this example, the programmable circuitry 712 implements the example signal generator controller circuitry 502, the example demodulator circuitry 504, the example circuit structure analyzer circuitry 505, the example image analyzer circuitry 506, and the example condition determiner circuitry 508.

The programmable circuitry 712 of the illustrated example includes a local memory 713 (e.g., a cache, registers, etc.). The programmable circuitry 712 of the illustrated example is in communication with main memory 714, 716, which includes a volatile memory 714 and a non-volatile memory 716, by a bus 718. The volatile memory 714 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 716 may be implemented by flash memory and/or any other desired type of memory device. Access to the main memory 714, 716 of the illustrated example is controlled by a memory controller 717. In some examples, the memory controller 717 may be implemented by one or more integrated circuits, logic circuits, microcontrollers from any desired family or manufacturer, or any other type of circuitry to manage the flow of data going to and from the main memory 714, 716.

The programmable circuitry platform 700 of the illustrated example also includes interface circuitry 720. The interface circuitry 720 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 722 are connected to the interface circuitry 720. The input device(s) 722 permit(s) a user (e.g., a human user, a machine user, etc.) to enter data and/or commands into the programmable circuitry 712. The input device(s) 722 can be implemented by, for example, an audio sensor, a microphone, a camera (still or video), a keyboard, a button, a mouse, a touchscreen, a trackpad, a trackball, an isopoint device, and/or a voice recognition system.

One or more output devices 724 are also connected to the interface circuitry 720 of the illustrated example. The output device(s) 724 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 720 of the illustrated example, thus, typically includes a graphics driver card, a graphics driver chip, and/or graphics processor circuitry such as a GPU.

The interface circuitry 720 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 726. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 700 of the illustrated example also includes one or more mass storage discs or devices 728 to store firmware, software, and/or data. Examples of such mass storage discs or devices 728 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 732, which may be implemented by the machine readable instructions of FIG. 6, may be stored in the mass storage device 728, in the volatile memory 714, in the non-volatile memory 716, and/or on at least one non-transitory computer readable storage medium such as a CD or DVD which may be removable.

FIG. 8 is a block diagram of an example implementation of the programmable circuitry 712 of FIG. 7. In this example, the programmable circuitry 712 of FIG. 7 is implemented by a microprocessor 800. For example, the microprocessor 800 may be a general-purpose microprocessor (e.g., general-purpose microprocessor circuitry). The microprocessor 800 executes some or all of the machine-readable instructions of the flowchart of FIG. 6 to effectively instantiate the circuitry of FIG. 5 as logic circuits to perform operations corresponding to those machine readable instructions. In some such examples, the circuitry of FIG. 5 is instantiated by the hardware circuits of the microprocessor 800 in combination with the machine-readable instructions. For example, the microprocessor 800 may be implemented by multi-core hardware circuitry such as a CPU, a DSP, a GPU, an XPU, etc. Although it may include any number of example cores 802 (e.g., 1 core), the microprocessor 800 of this example is a multi-core semiconductor device including N cores. The cores 802 of the microprocessor 800 may operate independently or may cooperate to execute machine readable instructions. For example, machine code corresponding to a firmware program, an embedded software program, or a software program may be executed by one of the cores 802 or may be executed by multiple ones of the cores 802 at the same or different times. In some examples, the machine code corresponding to the firmware program, the embedded software program, or the software program is split into threads and executed in parallel by two or more of the cores 802. The software program may correspond to a portion or all of the machine readable instructions and/or operations represented by the flowchart of FIG. 6.

The cores 802 may communicate by a first example bus 804. In some examples, the first bus 804 may be implemented by a communication bus to effectuate communication associated with one(s) of the cores 802. For example, the first bus 804 may be implemented by at least one of an Inter-Integrated Circuit (I2C) bus, a Serial Peripheral Interface (SPI) bus, a PCI bus, or a PCIe bus. Additionally or alternatively, the first bus 804 may be implemented by any other type of computing or electrical bus. The cores 802 may obtain data, instructions, and/or signals from one or more external devices by example interface circuitry 806. The cores 802 may output data, instructions, and/or signals to the one or more external devices by the interface circuitry 806. Although the cores 802 of this example include example local memory 820 (e.g., Level 1 (L1) cache that may be split into an L1 data cache and an L1 instruction cache), the microprocessor 800 also includes example shared memory 810 that may be shared by the cores (e.g., Level 2 (L2 cache)) for high-speed access to data and/or instructions. Data and/or instructions may be transferred (e.g., shared) by writing to and/or reading from the shared memory 810. The local memory 820 of each of the cores 802 and the shared memory 810 may be part of a hierarchy of storage devices including multiple levels of cache memory and the main memory (e.g., the main memory 714, 716 of FIG. 7). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 802 may be referred to as a CPU, DSP, GPU, etc., or any other type of hardware circuitry. Each core 802 includes control unit circuitry 814, arithmetic and logic (AL) circuitry (sometimes referred to as an ALU) 816, a plurality of registers 818, the local memory 820, and a second example bus 822. Other structures may be present. For example, each core 802 may include vector unit circuitry, single instruction multiple data (SIMD) unit circuitry, load/store unit (LSU) circuitry, branch/jump unit circuitry, floating-point unit (FPU) circuitry, etc. The control unit circuitry 814 includes semiconductor-based circuits structured to control (e.g., coordinate) data movement within the corresponding core 802. The AL circuitry 816 includes semiconductor-based circuits structured to perform one or more mathematic and/or logic operations on the data within the corresponding core 802. The AL circuitry 816 of some examples performs integer based operations. In other examples, the AL circuitry 816 also performs floating-point operations. In yet other examples, the AL circuitry 816 may include first AL circuitry that performs integer-based operations and second AL circuitry that performs floating-point operations. In some examples, the AL circuitry 816 may be referred to as an Arithmetic Logic Unit (ALU).

The registers 818 are semiconductor-based structures to store data and/or instructions such as results of one or more of the operations performed by the AL circuitry 816 of the corresponding core 802. For example, the registers 818 may include vector register(s), SIMD register(s), general-purpose register(s), flag register(s), segment register(s), machine-specific register(s), instruction pointer register(s), control register(s), debug register(s), memory management register(s), machine check register(s), etc. The registers 818 may be arranged in a bank as shown in FIG. 8.

Alternatively, the registers 818 may be organized in any other arrangement, format, or structure, such as by being distributed throughout the core 802 to shorten access time. The second bus 822 may be implemented by at least one of an I2C bus, a SPI bus, a PCI bus, or a PCIe bus.

Each core 802 and/or, more generally, the microprocessor 800 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 800 is a semiconductor device fabricated to include many transistors interconnected to implement the structures described above in one or more integrated circuits (ICs) contained in one or more packages.

The microprocessor 800 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 800, in the same chip package as the microprocessor 800 and/or in one or more separate packages from the microprocessor 800.

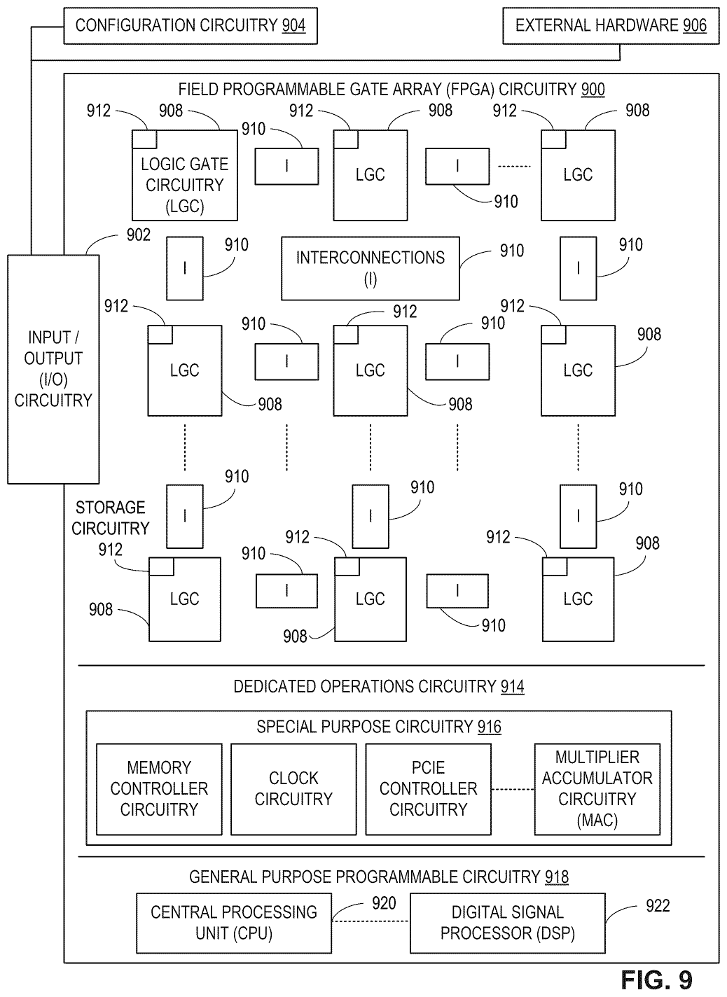

FIG. 9 is a block diagram of another example implementation of the programmable circuitry 712 of FIG. 7. In this example, the programmable circuitry 712 is implemented by FPGA circuitry 900. For example, the FPGA circuitry 900 may be implemented by an FPGA. The FPGA circuitry 900 can be used, for example, to perform operations that could otherwise be performed by the example microprocessor 800 of FIG. 8 executing corresponding machine readable instructions. However, once configured, the FPGA circuitry 900 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 800 of FIG. 8 described above (which is a general purpose device that may be programmed to execute some or all of the machine readable instructions represented by the flowchart of FIG. 6 but whose interconnections and logic circuitry are fixed once fabricated), the FPGA circuitry 900 of the example of FIG. 9 includes interconnections and logic circuitry that may be configured, structured, programmed, and/or interconnected in different ways after fabrication to instantiate, for example, some or all of the operations/functions corresponding to the machine readable instructions represented by the flowchart of FIG. 6. In particular, the FPGA circuitry 900 may be thought of as an array of logic gates, interconnections, and switches. The switches can be programmed to change how the logic gates are interconnected by the interconnections, effectively forming one or more dedicated logic circuits (unless and until the FPGA circuitry 900 is reprogrammed). The configured logic circuits enable the logic gates to cooperate in different ways to perform different operations on data received by input circuitry. Those operations may correspond to some or all of the instructions (e.g., the software and/or firmware) represented by the flowchart of FIG. 6. As such, the FPGA circuitry 900 may be configured and/or structured to effectively instantiate some or all of the operations/functions corresponding to the machine readable instructions of the flowchart of FIG. 6 as dedicated logic circuits to perform the operations/functions corresponding to those software instructions in a dedicated manner analogous to an ASIC. Therefore, the FPGA circuitry 900 may perform the operations/functions corresponding to the some or all of the machine readable instructions of FIG. 6 faster than the general-purpose microprocessor can execute the same.

In the example of FIG. 9, the FPGA circuitry 900 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 900 of FIG. 9 may access and/or load the binary file to cause the FPGA circuitry 900 of FIG. 9 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 900 of FIG. 9 to cause configuration and/or structuring of the FPGA circuitry 900 of FIG. 9, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 900 of FIG. 9 may access and/or load the binary file to cause the FPGA circuitry 900 of FIG. 9 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 900 of FIG. 9 to cause configuration and/or structuring of the FPGA circuitry 900 of FIG. 9, or portion(s) thereof.

The FPGA circuitry 900 of FIG. 9, includes example input/output (I/O) circuitry 902 to obtain and/or output data to/from example configuration circuitry 904 and/or external hardware 906. For example, the configuration circuitry 904 may be implemented by interface circuitry that may obtain a binary file, which may be implemented by a bit stream, data, and/or machine-readable instructions, to configure the FPGA circuitry 900, or portion(s) thereof. In some such examples, the configuration circuitry 904 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 906 may be implemented by external hardware circuitry. For example, the external hardware 906 may be implemented by the microprocessor 800 of FIG. 8.

The FPGA circuitry 900 also includes an array of example logic gate circuitry 908, a plurality of example configurable interconnections 910, and example storage circuitry 912. The logic gate circuitry 908 and the configurable interconnections 910 are configurable to instantiate one or more operations/functions that may correspond to at least some of the machine readable instructions of FIG. 6 and/or other desired operations. The logic gate circuitry 908 shown in FIG. 9 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 908 to enable configuration of the electrical structures and/or the logic gates to form circuits to perform desired operations/functions. The logic gate circuitry 908 may include other electrical structures such as look-up tables (LUTs), registers (e.g., flip-flops or latches), multiplexers, etc.

The configurable interconnections 910 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 908 to program desired logic circuits.

The storage circuitry 912 of the illustrated example is structured to store result(s) of the one or more of the operations performed by corresponding logic gates. The storage circuitry 912 may be implemented by registers or the like. In the illustrated example, the storage circuitry 912 is distributed amongst the logic gate circuitry 908 to facilitate access and increase execution speed.

The example FPGA circuitry 900 of FIG. 9 also includes example dedicated operations circuitry 914. In this example, the dedicated operations circuitry 914 includes special purpose circuitry 916 that may be invoked to implement commonly used functions to avoid the need to program those functions in the field. Examples of such special purpose circuitry 916 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 900 may also include example general purpose programmable circuitry 918 such as an example CPU 920 and/or an example DSP 922. Other general purpose programmable circuitry 918 may additionally or alternatively be present such as a GPU, an XPU, etc., that can be programmed to perform other operations.

Although FIGS. 8 and 9 illustrate two example implementations of the programmable circuitry 712 of FIG. 7, many other approaches are contemplated. For example, FPGA circuitry may include an on-board CPU, such as one or more of the example CPU 920 of FIG. 8. Therefore, the programmable circuitry 712 of FIG. 7 may additionally be implemented by combining at least the example microprocessor 800 of FIG. 8 and the example FPGA circuitry 900 of FIG. 9. In some such hybrid examples, one or more cores 802 of FIG. 8 may execute a first portion of the machine readable instructions represented by the flowchart of FIG. 6 to perform first operation(s)/function(s), the FPGA circuitry 900 of FIG. 9 may be configured and/or structured to perform second operation(s)/function(s) corresponding to a second portion of the machine readable instructions represented by the flowchart of FIG. 6, and/or an ASIC may be configured and/or structured to perform third operation(s)/function(s) corresponding to a third portion of the machine readable instructions represented by the flowchart of FIG. 6.

It should be understood that some or all of the circuitry of FIG. 5 may, thus, be instantiated at the same or different times. For example, same and/or different portion(s) of the microprocessor 800 of FIG. 8 may be programmed to execute portion(s) of machine-readable instructions at the same and/or different times. In some examples, same and/or different portion(s) of the FPGA circuitry 900 of FIG. 9 may be configured and/or structured to perform operations/functions corresponding to portion(s) of machine-readable instructions at the same and/or different times.

In some examples, some or all of the circuitry of FIG. 5 may be instantiated, for example, in one or more threads executing concurrently and/or in series. For example, the microprocessor 800 of FIG. 8 may execute machine readable instructions in one or more threads executing concurrently and/or in series. In some examples, the FPGA circuitry 900 of FIG. 9 may be configured and/or structured to carry out operations/functions concurrently and/or in series. Moreover, in some examples, some or all of the circuitry of FIG. 5 may be implemented within one or more virtual machines and/or containers executing on the microprocessor 800 of FIG. 8.

In some examples, the programmable circuitry 712 of FIG. 7 may be in one or more packages. For example, the microprocessor 800 of FIG. 8 and/or the FPGA circuitry 900 of FIG. 9 may be in one or more packages. In some examples, an XPU may be implemented by the programmable circuitry 712 of FIG. 7, which may be in one or more packages. For example, the XPU may include a CPU (e.g., the microprocessor 800 of FIG. 8, the CPU 920 of FIG. 9, etc.) in one package, a DSP (e.g., the DSP 922 of FIG. 9) in another package, a GPU in yet another package, and an FPGA (e.g., the FPGA circuitry 900 of FIG. 9) in still yet another package.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

Example methods, apparatus, systems, and articles of manufacture to enable relatively quick and accurate circuit condition determination are disclosed herein. Further examples and combinations thereof include the following:

Example 1 includes an apparatus to test a circuit, the apparatus comprising interface circuitry operatively coupled to an electron detector, the electron detector to output a signal corresponding to electron emissions from the circuit as the circuit is driven with a signal source and the circuit is rastered with an electron beam, machine readable instructions, and programmable circuitry to at least one of instantiate or execute the machine readable instructions to demodulate the signal, and generate an image based on the demodulated signal for determination of a condition of the circuit.

Example 2 includes the apparatus as defined in example 1, wherein the programmable circuitry is to determine the condition of the circuit based on the image.

Example 3 includes the apparatus as defined in any of examples 1 or 2, wherein the programmable circuitry is to control a frequency of an output of the signal source, and cause a lock-in amplifier to be locked to the frequency to demodulate the signal.

Example 4 includes the apparatus as defined in any of examples 1 to 3, wherein the programmable circuitry is to cause the signal source to provide an alternating current (AC) signal to the circuit.

Example 5 includes the apparatus as defined in any of examples 1 to 4, wherein a raw image of the signal is demodulated based on an output signal of the signal source.

Example 6 includes the apparatus as defined in example 5, wherein the programmable circuitry is to compare the raw image to the generated image to determine the condition of the circuit.

Example 7 includes the apparatus as defined in any of examples 5 or 6, wherein the output signal includes a frequency synchronization signal.

Example 8 includes a system to determine a condition of circuitry, the system comprising a signal source to be electrically coupled to an input of a circuit, an electron emitter to raster the circuit with an electron beam, a detector to measure an electron emission from the circuit, the detector to provide a signal corresponding to the measured electron emission, a lock-in amplifier to demodulate the signal from the detector, and an image digitizer to generate an image based on the demodulated signal.

Example 9 includes the system as defined in example 8, further including input/output (IO) probes to electrically couple the signal source to the input.

Example 10 includes the system as defined in any of examples 8 or 9, wherein the detector is to provide a secondary electron detector (SED) signal to the lock-in amplifier and the image digitizer.

Example 11 includes the system as defined in any of examples 8 to 10, wherein the lock-in amplifier is to scale the demodulated signal to provide phase resolution with respect to the image.

Example 12 includes the system as defined in any of examples 8 to 11, wherein the generated image is a phase-resolved image, and wherein the image digitizer is to further generate a raw scanning electron microscope (SEM) image.

Example 13 includes the system as defined in example 12, further including programmable circuitry to compare the phase-resolved image to the raw SEM image to determine the condition.

Example 14 includes the system as defined in any of examples 8 to 13, wherein the signal source provides a frequency synchronization signal to the lock-in amplifier for demodulation of the signal.

Example 15 includes the system as defined in any of examples 8 to 14, wherein the signal source is to drive the circuitry at a first frequency and at a second frequency, and the image digitizer is to generate first and second phase-resolved images based on the respective first and second frequencies.

Example 16 includes the system as defined in example 15, wherein the condition of the circuit is determined based on a comparison between the first and second phase-resolved images.

Example 17 includes a method of determining a condition of a circuit, the method comprising attaching probes to the circuit, driving, with a signal source, the circuit, rasterizing, with an electron beam from an electron emitter, the circuit, collecting, with an electron detector, a signal based on an emission from the circuit, demodulating, with a lock-in amplifier, the signal, and generating, with an image digitizer, a map of the circuit based on the demodulated signal.

Example 18 includes the method as defined in example 17, further including providing a frequency synchronization signal from the signal source to the lock-in amplifier.

Example 19 includes the method as defined in any of examples 17 or 18, further including comparing, by executing instructions with programmable circuitry, the generated map to a raw SEM image to determine the condition of the circuit.

Example 20 includes the method as defined in any of examples 17 to 19, further including scaling, by executing instructions with programmable circuitry, the signal to provide phase resolution with respect to the generated map.

From the foregoing, it will be appreciated that example systems, apparatus, articles of manufacture, and methods have been disclosed that enable relatively quick and accurate determination of circuit conditions and/or structure integrity. Examples disclosed herein effectively leverage an electron-beam of lock-in nano-probing tool as a scanning probe that can read outputs of a significant number of driven circuit elements in an image and can collect signals from circuitry that is typically inaccessible (e.g., either by topology or by obfuscating metal or dielectric) to traditional probe tips. Thus, landing output probes to read off AC signals from a circuit is not necessitated, and more probes are available to drive circuit inputs. As a result, throughput time for fault isolation work with AC probing of many circuit cells can be significantly reduced with examples disclosed herein that utilize contact-based AC probing.

Examples disclosed herein offer several benefits over known AC probing methodologies. Probing results can be more easily interpreted than convoluted outputs typically collected in cell probing. Further, signals that may be present in imaged circuitry outputs, but are not of interest for the FI job, are filtered from the onset since the demodulated image is generated at the frequency of interest. Additionally, there is a minimal impedance limitation generated by probing schemes in accordance with examples disclosed herein, thereby enabling relatively larger SNR collections in comparison to direct probing where the scope impedance is usually too high for the nano-circuit to drive adequately. AC signals captured by direct probes can be obscured by current absorbed or charging resulting from the electron beam landing on the nodes being probed. Therefore, it is common practice to blank the beam and probe the signals of interest without imaging. No such limitation is imposed in examples disclosed herein.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus to test a circuit, the apparatus comprising:
interface circuitry operatively coupled to an electron detector, the electron detector to output a signal corresponding to electron emissions from the circuit as the circuit is driven with a signal source and the circuit is rastered with an electron beam;
machine readable instructions; and
programmable circuitry to at least one of instantiate or execute the machine readable instructions to:
demodulate the signal; and
generate an image based on the demodulated signal for determination of a condition of the circuit.

2. The apparatus as defined in claim 1, wherein the programmable circuitry is to determine the condition of the circuit based on the image.

3. The apparatus as defined in claim 1, wherein the programmable circuitry is to:
control a frequency of an output of the signal source, and
cause a lock-in amplifier to be locked to the frequency to demodulate the signal.

4. The apparatus as defined in claim 1, wherein the programmable circuitry is to cause the signal source to provide an alternating current (AC) signal to the circuit.

5. The apparatus as defined in claim 1, wherein a raw image of the signal is demodulated based on an output signal of the signal source.

6. The apparatus as defined in claim 5, wherein the programmable circuitry is to compare the raw image to the generated image to determine the condition of the circuit.

7. The apparatus as defined in claim 5, wherein the output signal includes a frequency synchronization signal.

8. A system to determine a condition of circuitry, the system comprising:
a signal source to be electrically coupled to an input of a circuit;
an electron emitter to raster the circuit with an electron beam;
a detector to measure an electron emission from the circuit, the detector to provide a signal corresponding to the measured electron emission;
a lock-in amplifier to demodulate the signal from the detector; and
an image digitizer to generate an image based on the demodulated signal.

9. The system as defined in claim 8, further including input/output (IO) probes to electrically couple the signal source to the input.

10. The system as defined in claim 8, wherein the detector is to provide a secondary electron detector (SED) signal to the lock-in amplifier and the image digitizer.

11. The system as defined in claim 8, wherein the lock-in amplifier is to scale the demodulated signal to provide phase resolution with respect to the image.

12. The system as defined in claim 8, wherein the generated image is a phase-resolved image, and wherein the image digitizer is to further generate a raw scanning electron microscope (SEM) image.

13. The system as defined in claim 12, further including programmable circuitry to compare the phase-resolved image to the raw SEM image to determine the condition.

14. The system as defined in claim 8, wherein the signal source provides a frequency synchronization signal to the lock-in amplifier for demodulation of the signal.

15. The system as defined in claim 8, wherein the signal source is to drive the circuitry at a first frequency and at a second frequency, and the image digitizer is to generate first and second phase-resolved images based on the respective first and second frequencies.

16. The system as defined in claim 15, wherein the condition of the circuit is determined based on a comparison between the first and second phase-resolved images.

17. A method of determining a condition of a circuit, the method comprising:
attaching probes to the circuit;
driving, with a signal source, the circuit;
rasterizing, with an electron beam from an electron emitter, the circuit;
collecting, with an electron detector, a signal based on an emission from the circuit;
demodulating, with a lock-in amplifier, the signal; and
generating, with an image digitizer, a map of the circuit based on the demodulated signal.

18. The method as defined in claim 17, further including providing a frequency synchronization signal from the signal source to the lock-in amplifier.

19. The method as defined in claim 17, further including comparing, by executing instructions with programmable circuitry, the generated map to a raw SEM image to determine the condition of the circuit.

20. The method as defined in claim 17, further including scaling, by executing instructions with programmable circuitry, the signal to provide phase resolution with respect to the generated map.
